(19) United States
(12) Patent Application Publication
(10) Pub. No.: US 2009/0309610 A1
(43) Pub. Date: Dec. 17, 2009

(54) ELECTRICAL SAFETY DEVICES

(76) Inventor: Roy Appanna, London (GB)

Correspondence Address: WILEY HORTON, 215 SOUTH MONROE STREET, 2ND FLOOR, TALLAHASSEE, FL, 32301, US

(21) Appl. No.: 12/310,199

(22) PCT Filed: Aug. 14, 2007
(86) PCT No.: PCT/GB2007/003104

§ 371 Date: Aug. 17, 2009

(30) Foreign Application Priority Data
Aug. 16, 2006 (GB) 0616314.1

(51) Int. Cl. G01R 19/155; G01R 31/02; G08B 21/00

(52) U.S. Cl. 324/537; 340/657

(57) ABSTRACT

A device for detecting the presence or absence of a potential difference across two conductive elements, including means to provide an indication of a potential difference between said two conductive elements, the means having a test connection between the two elements comprising two spaced conductive lines in parallel, each line having self testing means including detecting means connected across said two lines and means to apply a test voltage through said two lines to test the integrity of the lines and their connection to the conductive elements with indicator means to provide an alarm signal should the detector indicate an abnormal response in said test voltage indicative of a fault in the line connections and/or one or other of the lines.

This invention relates to an electrical safety device, which seeks to reduce the possibility of electric shock to persons working with electrical equipment and is particularly, but not exclusively, related to electrified rail installations.

When personnel work with electrical systems, such as electrified track, it is desirable that the personnel can determine without doubt that the power to the system or track has been isolated before personnel come into contact with the system or in the case of rail systems, step on to the track to carry out maintenance.

When track or associated systems are to be maintained, and personnel have to step onto the track, the normal procedure is for the power to be isolated for the section of track on which work is to be carried out. Often the isolation of the power supply is carried out at a central control room and personnel need to be able to be confident that the power to the track has indeed be switched off.

In a known arrangement and method of working, portable test equipment is used to check that the conducting rails are de-energised prior to commencing work on the track. This method has the disadvantage that the operator has to get on to the track before the check for de-energisation can be made. Furthermore the equipment can give a false reading indicating no current is present, if there is a poor electrical connection to the track or a break in the wiring of the device such a blown fuse. It is also possible for the current to be de-energised and then unexpectedly energised.

A device for detecting a hazardous potential difference between conducting rails of a railway track is shown in EP 11429129 which has a connecting cable connected via rail terminal plates to the normally live rail and the negative or earth rail of the track. If a current flows, a warning light or alarm indicates that the power has not been isolated.

The device disclosed in EP 11429129 incorporates a self test system, by which the two rail terminal plates may be connected together and a test current is passed through the connecting cable. This self test facility tests the integrity of the connecting parts. The problem with this device is that in operation, should a rail terminal plate or connecting cable fail, the device will indicate that the track is not energised and this may result in a false positive indication that the track is safe to operate on. There is also a risk from unexpected trains and the rails becoming live whilst an operator is on the track to perform a measurement. The present invention seeks to overcome the potential risks that exist with the prior art devices.

According to the present invention there is provided a device for detecting the presence or absence of a potential difference across two conductive elements, including means to provide an indication of a potential difference between said two conductive elements, the means having a test connection between the two elements comprising two spaced conductive lines in parallel, each line having self testing means including detecting means connected across said two lines and means to apply a test signal through said two lines to test the integrity of the lines and their connection to the conductive elements with indicator means to provide a fault signal should the detector indicate an abnormal response in said test signal indicative of a fault in the line connections and/or one or other of the lines.

Preferably, the device includes a logic unit adapted to be detachable from a base unit to which said lines are connected.

Preferably the indicator means comprises an oscillator responsive to an abnormal response in said test signal.

Preferably the device includes a power supply.

Preferably the power supply includes a rechargeable battery chargeable from current in said two conductive elements.

Preferably the conductive elements comprise positive and negative conductive rails of a four rail railway track.

In an alternative application, the conductive elements comprise a positive and earth rail of a three rail railway track.

Preferably the device is permanently connected to the said conductive elements.

Preferably the device is able to detect the presence of both direct current (DC) and alternating current (AC) voltages.

Preferably, the indicating means includes warning lights and/or an audible alarm.

In a preferred embodiment, when applied to a rail track, two or more of the electrical safety devices are provided along the rail track. In this embodiment, the devices may be provided at spaced intervals along the track.

In this embodiment, the devices are preferably networked and may be monitored by a local and or central control centre.

Preferred embodiments of the present invention will now be described by way of example with reference to the following drawings in which:

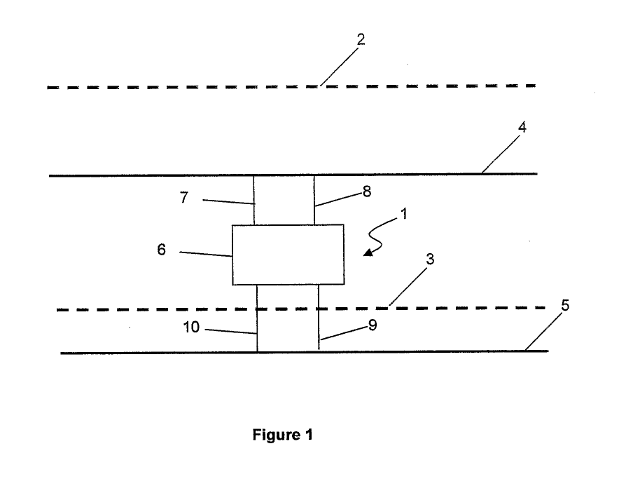

FIG. 1 shows a first embodiment of the present invention;

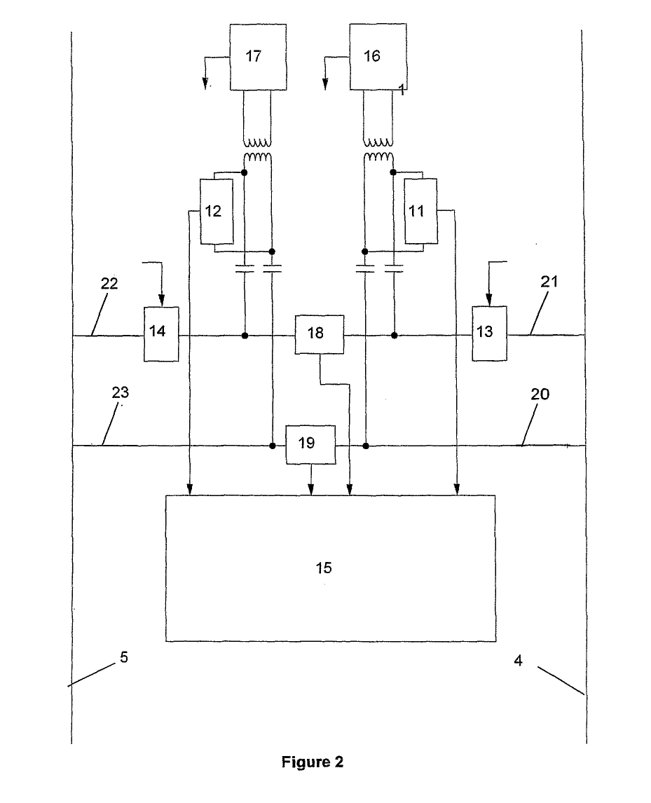

FIG. 2 shows a further preferred embodiment of the present invention.

Traction power for a typical rail application is supplied by a 630V DC ground rail system configured as a four rail arrangement. Two of the rails are the running rails and are not electrified. One of the running rails is assigned as a continues earth rail. The other two rails comprise current rails for supplying current to the train motors. One of the current rails is at a potential of +420V and the other at −210V. The system is earthed through bleed resistors.

FIG. 1 shows a first embodiment of the present invention. The device, shown generally as 1, has a test connection 7,10 and 8,9 between two conductive elements 4,5. These two conductive elements 4,5 are the positive and negative current rails of a four rail train track. In the case of a three rail system, the two conductive elements are the positive rail and the ground rail. In normal operation of the device of the present invention, a test connection 7,10 and 8,9 is maintained by connecting the device 1 across the conductive elements. The device 1 then tests for the presence or absence of a potential difference. If a potential difference is detected, then an audible and/or visual alarm is activated to warn the operators on the track that the power rails are live and not safe to work on. The test connection is formed as two spaced conductive lines 7,8 and 9,10 connected between the device 1 and each of the conductive elements. In addition to testing for the presence of a potential difference between the conductive elements, the device also performs a self test to ensure that the test connection is constantly maintained. The two conductive lines 7,8 and 9,10 are connected to the conductive elements 4,5 with a small separation so that the conductive elements 4,5 form part of a circuit. The self test in this first embodiment is performed by applying a small potential difference across the conductive element 4,5 by the conductive lines 7,8 and 9,10. A voltage detector measures the voltage drop across the conductive elements. If the voltage drop should fall outside of a predetermined range, this indicates that there is a fault or that the device has become disconnected from the conductive elements. Without this self test, it would be possible for the device to indicate the track was safe if any of the connections of the device become detached from the conductive elements.

In a further embodiment of the present invention shown in FIG. 2, the device is attached to the conductive elements 4,5 using two lines 20,21 and 22,23 thereby forming a circuit from the device through the first line 21,22 to the rail 4 and then from the rail 5 through the second line 20,23 to the device. A current in the rails is detected by the voltage detectors 18,19. To self test the integrity of the connection between the device and the rails, an oscillator 16,17 is provided and, during self test of the device, supplies a potential difference across the lines at a predetermined frequency. A frequency detector 11,12 detects the frequency of the voltage across the lines. A logic unit 15 compares the frequency of the voltage indicated by the frequency detector 11,12 with the frequency of the voltage applied to the lines 21,20 and 22,23 by the oscillator 16,17 and if there should be a difference or abnormal response, this serves to indicate that the device may have become detached from the rails or conductive elements 4,5 or that there is a fault in the lines 20-23 and a warning is indicated.

The logic unit 15 comprises a plug-in unit designed to be plugged in a base unit, in a detachable manner, from which the lines 21-23 are connected in order that the logic unit 15 may be readily replaced if a fault should occur in the logic unit itself.

The device of either the first or further embodiments may be provided with a permanent power supply or with a battery for portable use of the device. The battery in the system may be provided with a battery charger which draws current from the track or conductive elements when the power is supplied to the track. When the power is switched off for track maintenance purposes, the device is then powered by the charged battery.

The device is provided with an indicator to indicate the normal operation of the device and for example that there are no problems with the power supply to the device.

In the embodiment shown, the normal operation of the device is not indicated, but power on, power off and the presence of a fault are indicated.

The device may be connected in a permanent fashion to the track at spaced intervals. By providing a permanent system, the risk to an operator in attaching a portable device to potentially live track is reduced. Each of the devices may be networked and monitored by a local or central control centre. By providing a number of the devices along a section of track or of the whole rail network, the functionality of the devices may be monitored and an alarm sounded if, on the basis if one or more of the devices should differ in state from that expected and indicated by adjacent devices on the track.

The device may be located above the track level for example on a tunnel wall or other mounting point to avoid an operator having to step on the track to view or use the device.

The device may be provided with a swipe card system, whereby operators working on the track can swipe in with a unique swipe card at a particular device and the location of the operator can then be monitored by a local or central control room.

The device is provided with a housing suitable for the environmental conditions of the application.

The device is provided with both audible and visual warning indicators. The visual indicator is visible from at least 5 meters.

1. A device for detecting the presence of a potential difference across two conductive elements, including means to provide an indication of a potential difference between said two conductive elements, the means having a test connection between the two elements comprising two spaced conductive lines in parallel, each line having self testing means including detecting means connected across said two lines and means to apply a test signal through said two lines to test the integrity of the lines and their connection to the conductive elements with indicator means to provide a fault signal should the detector indicate an abnormal response in said test signal indicative of a fault in the line connections and/or one or other of the lines.

2. A device according to claim 1, including a logic unit adapted to be detachable from a base unit to which said lines are connected.

3. A device according to claim 1, wherein the indicator means comprises an oscillator responsive to an abnormal response in said test signal.

4. A device according to claim 1, wherein the device includes a power supply.

5. A device according to claim 4, wherein the power supply includes a rechargeable battery chargeable from current in said two conductive elements.

6. A device according to claim 1, wherein the conductive elements comprise positive and negative conductive rails of a four rail railway track.

7. A device according to claim 1, wherein the conductive elements comprise a positive and earth rail of a three rail railway track.

8. A device according to claim 1, wherein the device is permanently connected to the said conductive elements.

9. A device according to claim 1, wherein, the indicating means is selected from the group consisting of a warning light and an audible alarm.

10. A device according to claim 1, wherein, when applied to a rail track, two or more of the electrical safety devices are provided along the rail track.

11. A device according to claim 10, wherein the devices may be provided at spaced intervals along the track.

12. A device according to claim 10, wherein the devices are preferably networked and may be monitored by a local or a central control centre.

13. A device for detecting the presence of a potential difference across two conductive elements, comprising:
a. a logic unit adapted to be detachable from a base unit to which said lines are connected;
b. a potential difference detector connected between said two conductive elements;
c. a test connection between said two elements comprising two spaced conductive lines in parallel, each line having self testing means including detecting means connected across said two lines and means to apply a test signal through said two lines to test the integrity of the lines and their connection to the conductive elements with indicator means to provide a fault signal should the detector indicate an abnormal response in said test signal indicative of a fault in the line connections and/or one or other of the lines; and
d. wherein said indicator means comprises an oscillator responsive to an abnormal response in said test signal

14. A device according to claim 2, wherein the indicator means comprises an oscillator responsive to an abnormal response in said test signal.

15. A device according to claim 2, wherein the device includes a power supply.

16. A device according to claim 3, wherein the device includes a power supply.

17. A device according to claim 6, wherein the conductive elements comprise positive and negative conductive rails of a four rail railway track.

18. A device according to claim 3, wherein the conductive elements comprise a positive and earth rail of a three rail railway track.

19. A device according to claim 2, wherein the device is permanently connected to the said conductive elements.

20. A device according to claim 2, wherein the device is permanently connected to the said conductive elements.
